(19) United States
(12) Patent Application Publication
(10) Pub. No.: US 2024/0210818 A1
(43) Pub. Date: Jun. 27, 2024

(54) IMPRINT APPARATUS, IMPRINT METHOD, AND ARTICLE MANUFACTURING METHOD

(71) Applicant: CANON KABUSHIKI KAISHA, Tokyo (JP)

(72) Inventor: SOUSHI YAMAGUCHI, Tochigi (JP)

(21) Appl. No.: 18/533,376

(22) Filed: Dec. 8, 2023

(30) Foreign Application Priority Data
Dec. 22, 2022 (JP) 2022-205989

(51) Int. Cl. G03F 7/00

(52) U.S. Cl. CPC G03F 7/0002; H01L 21/31144

(57) ABSTRACT

An imprint apparatus that forms a pattern on each of a plurality of shot regions of a substrate by performing an imprint process is provided. The apparatus includes a controller configured to detect a timing at which a time until completion of a process of the substrate matches a predetermined time, wherein the plurality of shot regions are classified into a plurality of processing time groups, and each processing time group is associated with a processing time required for a process of each shot region belonging to the processing time group, and wherein the controller is configured to obtain a total time for processing unprocessed shot regions among the plurality of shot regions of the substrate based on the processing time associated with the processing time group to which each of the unprocessed shot regions belongs.

### BACKGROUND OF THE INVENTION

### Field of the Invention

The present invention relates to an imprint apparatus, an imprint method, and an article manufacturing method.

### Description of the Related Art

In the manufacture of an article such as a semiconductor, in order to improve throughput, two hands can be provided in a substrate conveyance robot that exchanges a substrate with a substrate stage. While a substrate placed on the substrate stage is processed, the substrate conveyance robot holding a substrate to be processed next with one hand can wait at a substrate exchange position. When processing of the substrate placed on the substrate stage ends, the substrate conveyance robot can receive the substrate placed on the substrate stage with the other hand, and place, on the substrate stage, the substrate held with the one hand of the substrate conveyance robot. If the waiting time of the substrate conveyance robot at the substrate exchange position varies between substrates, the influence of heat which the substrate receives at the substrate exchange position can change, so that the temperature of the substrate placed on the substrate stage can vary. This can cause a variation in overlay accuracy. Japanese Patent Laid-Open No. 2000-200820 describes a substrate conveyance apparatus provided with a temperature adjustment unit. However, providing a temperature adjustment unit in a substrate conveyance apparatus can lead to a complicated arrangement of the substrate conveyance apparatus.

### SUMMARY OF THE INVENTION

The present invention provides a technique advantageous in reducing a variation in waiting time of a substrate to be processed next.

One of aspects of the present invention provides an imprint apparatus that forms a pattern on each of a plurality of shot regions of a substrate by performing an imprint process, the apparatus comprising a controller configured to detect a timing at which a time until completion of a process of the substrate matches a predetermined time, wherein the plurality of shot regions are classified into a plurality of processing time groups, and each processing time group is associated with a processing time required for a process of each shot region belonging to the processing time group, and wherein the controller is configured to obtain a total time for processing unprocessed shot regions among the plurality of shot regions of the substrate based on the processing time associated with the processing time group to which each of the unprocessed shot regions belongs.

Further features of the present invention will become apparent from the following description of exemplary embodiments with reference to the attached drawings.

### BRIEF DESCRIPTION OF THE DRAWINGS

FIG. 1 is a view schematically showing the arrangement of an imprint apparatus according to an embodiment;

FIGS. 2A to 2F are views for explaining a dispense process and an imprint process;

FIG. 3 is a view exemplarily showing processes of a plurality of shot regions;

FIG. 4 is a timing chart showing the relationship between processes of the plurality of shot regions of a substrate and conveyance of the next substrate;

FIG. 5 is a flowchart exemplarily showing an operation of the imprint apparatus according to the embodiment;

FIG. 6 is a view exemplarily showing an operation of an imprint apparatus according to another embodiment; and

FIGS. 7A to 7F are views exemplarily showing an article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

In this specification and the accompanying drawings, directions will be described on an XYZ coordinate system. Directions parallel to the X-axis, the Y-axis, and the Z-axis are the X direction, the Y direction, and the Z direction, respectively. The X direction, the Y direction, and the Z direction can be understood as directions orthogonal to each other, or directions intersecting with each other. The θX-axis, the θY-axis, and the θZ-axis are a rotation about the X-axis, a rotation about the Y-axis, and a rotation about the Z-axis, respectively.

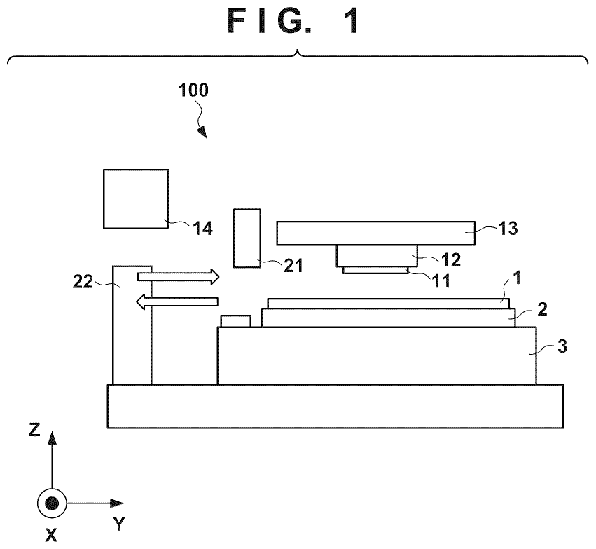

FIG. 1 schematically shows the arrangement of an imprint apparatus 100 according to an embodiment. The imprint apparatus 100 arranges an imprint material on a substrate 1, brings a mold 11 into contact with the imprint material, and cures the imprint material, thereby forming a pattern made of a cured product of the imprint material. As the imprint material, a curable composition (to be also referred to a resin in an uncured state) that is cured by receiving curing energy is used. As the curing energy, for example, light selected from the wavelength range of 10 nm (inclusive) to 1 mm (inclusive) (for example, infrared light, a visible light beam, ultraviolet light, or the like), or heat can be used. The curable composition can be a composition that is cured by irradiation of light. A photo-curable composition that is cured by irradiation of light contains at least a polymerizable compound and a photopolymerization initiator, and may contain a nonpolymerizable compound or a solvent as needed. The nonpolymerizable compound is at least one material selected from the group consisting of a sensitizer, a hydrogen donor, an internal mold release agent, a surfactant, an antioxidant, and a polymer component. The imprint material can be arranged on a substrate in a droplet shape or in an island or film shape formed by connecting a plurality of droplets. The viscosity (the viscosity at 25° C.) of the imprint material can be, for example, 1 mPa·s (inclusive) to 100 mPa·s (inclusive). As the material of a substrate, for example, glass, ceramic, a metal, a semiconductor, a resin, or the like can be used. A member made of a material different from that of the substrate may be formed on the surface of the substrate, as needed. The substrate can be, for example, a silicon wafer, a semiconductor compound wafer, or silica glass.

The imprint apparatus 100 can include a substrate stage 3 that includes a substrate holding unit 2 for holding the substrate 1. The substrate stage 3 can be driven by a substrate driving mechanism (not shown). Thus, the substrate 1 can be driven about a plurality of axes (for example, three axes of the X-, Y-, and θZ-axes). The imprint apparatus 100 includes a mold driving mechanism 13 that drives the mold 11. The mold driving mechanism 13 can be configured to drive the mold 11 by driving a mold holding unit 12 that holds the mold 11. The mold driving mechanism 13 can be configured to drive the mold 11 about a plurality of axes (for example, six axes of the X-, Y-, Z-, θX-, θY-, and θZ-axes). The substrate driving mechanism which drives the substrate stage 3 and the mold driving mechanism 13 form an alignment mechanism that drives the substrate 1 and the mold 11 so as to adjust the relative position between the substrate 1 and the mold 11.

As a component for curing the imprint material, the imprint apparatus 100 can include a light source (not shown) that generates light to be applied to the imprint apparatus brought into contact with the mold 11. The light source can include, for example, a halogen lamp or a mercury lamp that generates i-line and/or g-line. The imprint apparatus 100 can also include a dispenser 21 (supply unit) that supplies the imprint material onto the substrate 1. A spread accelerator and/or an adhesive material used to increase the adhesiveness between the imprint material and the substrate 1 may be supplied onto the substrate 1 in advance outside the imprint apparatus 100.

The imprint apparatus 100 can include a conveyance robot 22 that is used to, after a process of the substrate 1 is completed, exchange the processed substrate 1 and the substrate 1 to be processed next. In order to efficiently exchange the substrates 1, the conveyance robot 22 can include two hands (not shown). Before a process of the substrate 1 on the substrate holding unit 2 is completed, the conveyance robot 22 can hold the substrate 1 to be processed next with one hand, and be made to wait at a substrate exchange position. The substrate exchange position is a position where the processed substrate 1 is unloaded from the substrate stage 3 (substrate holding unit 2) to the conveyance robot 22, and the substrate 1 to be processed next is loaded from the conveyance robot 22 to the substrate holding unit 2.

If the conveyance robot 22 arrives at the substrate exchange position excessively earlier than completion of the process of the substrate 1 on the substrate stage 3, the waiting time during which the substrate 1 to be processed next is kept waiting at the substrate exchange position becomes excessively long. In this case, there are concerns about the influence of heat on the substrate 1 to be processed next. On the other hand, if arrival of the conveyance robot 22 at the substrate exchange position is later than completion of the process of the substrate 1 on the substrate 3, the substrates cannot be exchanged, resulting in a decrease in throughput.

Therefore, it is important to more accurately control the timing of starting, by the conveyance robot 22, conveyance of the substrate 1 to be processed next, and the timing of exchanging the substrate 1 to be processed next at the substrate exchange position. The waiting time of the substrate 1 to be processed next at the substrate exchange position depends on the heat control ability of the chamber of the imprint apparatus 100, influence of heat (the thermal expansion coefficient of the substrate), the required overlay accuracy, and the like. For example, the waiting time is desirably within 3 sec, 2.5 sec, or 2 sec.

The imprint apparatus 100 can include a controller 14. The controller 14 can be configured to control components of the imprint apparatus 100, for example, the substrate driving mechanism that drives the substrate stage 3, the mold driving mechanism 13, the dispenser 21, and the conveyance robot 22. The controller 14 can be formed from, for example, a PLD (an abbreviation for Programmable Logic Device) such as an FPGA (an abbreviation for Field Programmable Gate Array), an ASIC (an abbreviation for Application Specific Integrated Circuit), a general-purpose or dedicated computer installed with a program, or a combination of all or some of these components.

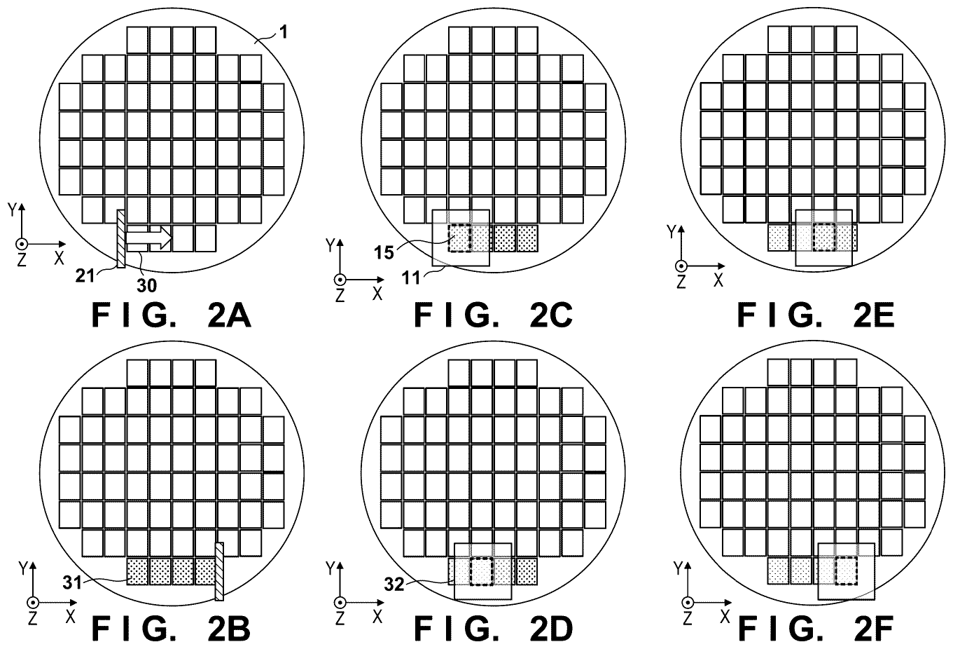

With reference to FIGS. 2A to 2F, a dispense process and an imprint process will be described below. FIGS. 2A to 2F schematically show the array of a plurality of shot regions (shot region array) and the relative position between the substrate 1 and the dispenser 21. Usually, the relative position is controlled by moving the substrate 1 (substrate stage 3), but the dispenser 21 may be driven.

In this embodiment, a plurality of shot regions of the substrate 1 are classified into a plurality of multi dispense groups. Each multi dispense group is formed from at least one shot region, and preferably at least two shot regions. Each multi dispense group is formed from shot regions on which the dispenser 21 continuously arranges the imprint material without undergoing the imprint process.

FIG. 2A shows a state in which the substrate 1 is arranged at an application start position for the shot regions forming one multi dispense group. In the state shown in FIG. 2A, the dispenser 21 starts to apply the imprint material onto the substrate 1. After that, while changing the relative position between the dispenser 21 and the substrate 1 as indicated by an arrow, the dispenser 21 applies the imprint material onto the shot regions forming the multi dispense group. FIG. 2B shows a state in which application (dispense process) of the imprint material is completed up to the trailing shot region where the imprint material is applied last among the shot regions forming one multi dispense group.

FIG. 2C shows a state of the imprint process on the first shot region of the shot regions forming the multi dispense group onto which the imprint material has been applied. Here, in this specification, the imprint process includes a step of bringing a pattern region 15 of the mold 11 into contact with the imprint material already applied or arranged on the shot region, a step of curing the imprint material, and a step of separating the mold 11 from the cured imprint material. In this specification, the imprint process does not include the dispense process of applying or arranging the imprint material on the shot region. The first shot region may or may not be the shot region (leading shot region) onto which the imprint material has been applied first among the shot regions forming the multi dispense group.

FIG. 2D shows a state of the imprint process on the second shot region of the shot regions forming the multi dispense group onto which the imprint material has been applied. The second shot region may or may not be the shot region onto which the imprint material has been applied second among the shot regions forming the multi dispense group.

FIG. 2E shows a state of the imprint process on the third shot region of the shot regions forming the multi dispense group onto which the imprint material has been applied. The third shot region may or may not be the shot region onto which the imprint material has been applied third among the shot regions forming the multi dispense group.

FIG. 2F shows a state of the imprint process on the fourth (in this example, final) shot region of the shot regions forming the multi dispense group onto which the imprint material has been applied. The fourth shot region may or may not be the shot region onto which the imprint material has been applied fourth among the shot regions forming the multi dispense group.

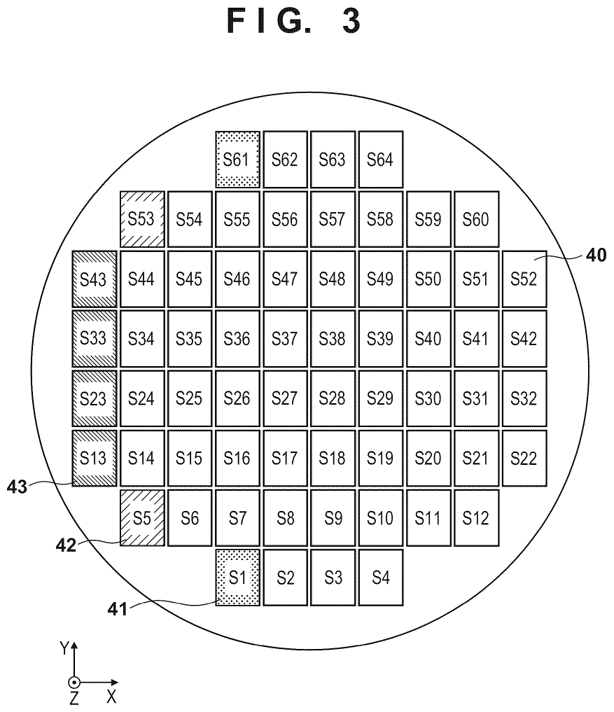

With reference to FIG. 3, processes of the plurality of shot regions of the substrate 1 will be exemplarily described. The process of each shot region includes the dispense process and the imprint process. In FIG. 3, Sx (x=1 to 64) is an identifier for identifying the shot region. x indicates the shot region number. The imprint processes on the plurality of shot regions S1 to S64 can be performed in the ascending order of the shot region number. In the example shown in FIG. 3, one row (for example, the shot regions S1, S2, S3, and S4) forms one multi dispense group. For the shot regions (for example, the shot regions S1, S2, S3, and S4) forming one multi dispense group (one row), the imprint material is continuously applied without undergoing the imprint process. The shot region onto which the imprint material is applied first among the shot regions forming one multi dispenser group (one row) is defined as a leading shot region. In the example shown in FIG. 3, the shot regions S1, S5, S13, S23, S33, S43, S53, and S61 are the leading shot regions.

For example, in the process of one multi dispense group formed from the shot regions S1, S2, S3, and S4, the dispense process is performed in which the imprint material is continuously applied onto the shot regions S1, S2, S3, and S4 without undergoing the imprint process. Then, the imprint process is continuously performed on the shot regions S1, S2, S3, and S4.

In the process of one multi dispense group formed from the shot regions S5 to S12, the dispense process is performed in which the imprint material is continuously applied onto the shot regions S5 to S12 without undergoing the imprint process. Then, the imprint process is continuously performed on the shot regions S5 to S12. The dispense process and imprint process can be performed for the remaining multi dispense groups in accordance with a similar rule.

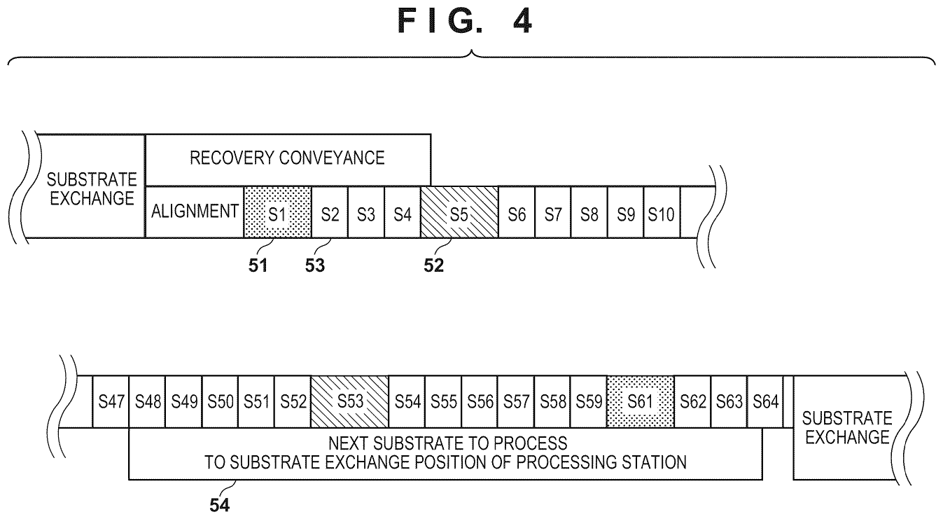

FIG. 4 is a timing chart showing the procedure of processing the substrate 1 in time series in accordance the example shown in FIG. 3. For the illustrative convenience, the shot regions S11 to S46 are omitted.

After the substrates are exchanged (the substrate 1 is unloaded from the substrate stage 3 and the new substrate 1 is loaded to the substrate stage 3), alignment of the new substrate 1 (to be simply referred to as the substrate 1 hereinafter) is performed. After that, the process (dispense process and imprint process) of the shot regions S1 to S4 forming the first multi dispense group is performed. More specifically, first, the dispense process is performed in which the imprint material is continuously applied onto the shot regions S1, S2, S3, and S4 without undergoing the imprint process. The shot region S1 is the leading shot region onto which the imprint material is applied first in the multi dispense group (shot regions S1, S2, S3, and S4). The shot regions S2, S3, and S4 are subsequent shot regions onto which the imprint material is applied second and thereafter in the multi dispense group (shot regions S1, S2, S3, and S4). After the continuous dispense process on the shot regions S1, S2, S3, and S4, the imprint process is continuously performed on the shot regions S1, S2, S3, and S4.

A processing time 51 required for the process of the shot region S1 as the leading shot region is the time required from the start of the process of the shot region S1 to the completion of the process of the shot region S1. That is, the processing time 51 includes the time for continuously applying the imprint material onto the shot regions S1 to S4 forming the multi dispense group to which the shot region S1 belongs, and the time required for the imprint process on the shot region S1.

A processing time 53 required for the process of the shot region S2 as one of the subsequent shot regions is the time required for the imprint process on the shot region S2. That is, the processing time 53 required for the process of the shot region S2 as the subsequent shot region is handled as not including the time required for application of the imprint material onto the shot region S2.

This also applies to the shot regions forming the subsequent multi dispense groups. For example, a processing time 52 required for the process of the shot region S5 as the leading shot region is the time required from the start of the process of the shot region S5 to the completion of the process of the shot region S5. That is, the processing time 52 includes the time for continuously applying the imprint material onto the shot regions S5 to S12 forming the multi dispense group to which the shot region S5 belongs, and the time required for the imprint process on the shot region S5. A processing time required for the process of the shot region S6 as one of the subsequent shot regions is the time required for the imprint process on the shot region S6. That is, the processing time required for the process of the shot region S6 as the subsequent shot region is handled as not including the time required for application of the imprint material onto the shot region S6.

Similarly, a processing time required for the process of the shot region S53 as the leading shot region is the time required from the start of the process of the shot region S53 to the completion of the process of the shot region S53. That is, the processing time required for the process of the shot region S53 includes the time for continuously applying the imprint material onto the shot regions S53 to S59 forming the multi dispense group, and the time required for the imprint process on the shot region S53. A processing time required for the process of the shot region S54 as one of the subsequent shot regions is the time required for the imprint process on the shot region S54. That is, the processing time required for the process of the shot region S54 as the subsequent shot region is handled as not including the time required for application of the imprint material onto the shot region S54.

A conveyance time 54 is the time required by the conveyance robot 22 for obtaining the substrate 1 to be processed next from the supply source (for example, a cassette, a temperature adjustment unit, a prealigner, or the like) and conveying it to the substrate exchange position. The conveyance time 54 may be handled as a constant time. If there is a factor that changes the conveyance time 54, the controller 14 may update the conveyance time 54 based on the change of the factor.

The controller 14 sequentially calculates the time (remaining processing time) from the current time to the time at which the process of the shot region to be processed last is completed, thereby detecting the timing at which the remaining processing time matches the conveyance time 54. In other words, the controller 14 detects the timing at which the time (remaining processing time) until completion of the process of the substrate 1 as the current process target matches a predetermined time (conveyance time 54). In accordance with the timing, the controller 14 causes the conveyance robot 22 to start an operation of conveying the substrate to be processed next to the substrate stage 3.

As can be seen from the example shown in FIGS. 3 and 4, the processing time required for the process of each of the plurality of shot regions of the substrate 1 can be classified into one of a plurality of processing time groups and handled. Each processing time group can be associated with the processing time required for the process of each shot region belonging to the processing time group. For example, the processing time required for the process of the leading shot region S1 of the multi dispense group formed from four shot regions S1 to S4 is the processing time 53 as described above. The processing time required for the process of the leading shot region S61 of the multi dispense group similarly formed from four shot regions S61 to S64 can be considered to be classified into the same processing time group as the processing time 53.

Both of the multi dispense group formed from the shot regions S5 to S12 and the multi dispense group formed from the shot regions S53 to S60 are each formed from eight shot regions. Accordingly, it can be considered that the processing time required for the process of the leading shot region S5 and the processing time required for the process of the leading shot region S53 are classified into the same processing time group.

All of the four multi dispense groups formed from the shot regions S13 to S22, the shot regions S23 to S32, the shot regions S33 to S42, and the shot regions S43 to S52, respectively, are each formed from 10 shot regions. Accordingly, it can be considered that the processing time required for the process of the leading shot region S13, that of the leading shot region S23, that of the leading shot region S33, and that of the leading shot region S43 are classified into the same processing time group.

The remaining shot regions S2 to S4, S6 to S12, S14 to S22, S24 to S32, S34 to S42, S44 to S52, S54 to S60, and S62 to S64 are shot regions on which the imprint process alone is to be performed. Accordingly, it can be considered that the processing times required for the processes of these shot regions are classified into the same processing time group.

The controller 14 can be configured to obtain the total time (remaining processing time) for processing unprocessed shot regions among the plurality of shot regions of the substrate 1 based on the processing time associated with the processing time group to which each of the unprocessed shot regions belongs. With this, the controller 14 can detect the timing at which the time (remaining processing time) until completion of the process of the substrate 1 as the current process target matches the predetermined time (a conveyance time 54).

The controller 14 can control the dispenser 21, based on control information including information used to control an imprint material application process, so as to continuously apply the imprint material onto the designated number of shot regions without undergoing the imprint process. The controller 14 can decide the plurality of processing time groups based on the control information. The controller 14 can classify each of the plurality of shot regions into one of the plurality of processing time groups based on the control information.

The plurality of processing time groups can include at least two groups in accordance with the number of shot regions onto which the imprint material is to be continuously applied without undergoing the imprint process. At least one processing time group of the plurality of processing time groups can be formed from the leading shot region on which the imprint material is to be arranged first in the multi dispense group. The multi dispense group is formed from the shot regions onto which the imprint material is to be continuously applied without undergoing the imprint process. At least one other processing time group of the plurality of processing time groups can be formed from a subsequent shot region onto which the imprint material is applied second or thereafter in the multi dispense group. The controller 14 may be configured to update, based on the time required for the process of the shot region having undergone the imprint process among the plurality of shot regions, the processing time associated with the processing time group to which the shot region belongs.

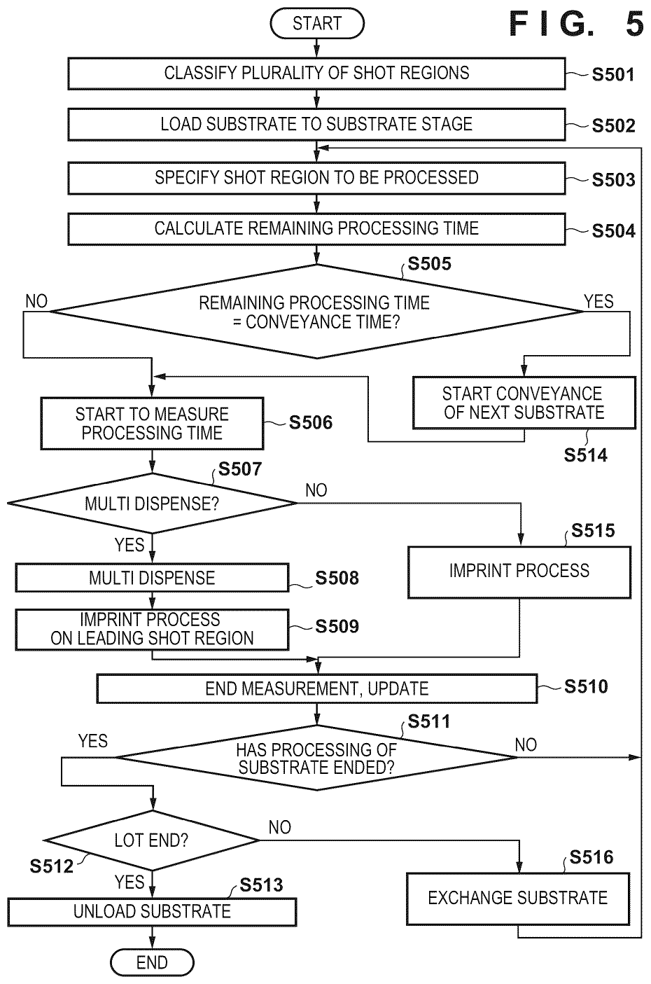

FIG. 5 exemplarily shows an operation of the imprint apparatus 100. The operation shown in FIG. 5 is controlled by the controller 14. In step S501, the controller 14 reads control information (recipe file), and classifies a plurality of shot regions of a substrate into a plurality of processing time groups based on the control information. More specifically, the controller 14 classifies each of the plurality of shot regions of the substrate into one of the plurality of processing time groups based on the control information. For example, in the example shown in the FIG. 3, the controller 14 can classify the shot regions S1 and S61 into a first processing time group, and classify the shot regions S5 and S53 into a second processing time group. In addition, the controller 14 can classify the shot regions S13, S23, S33, and S43 into a third processing time group, and classify the remaining shot regions into a fourth processing time group.

In step S502, the controller 14 controls the conveyance robot 22 so as to load the first substrate of a plurality of substrates forming a lot to the substrate stage 3. In step S503, the controller 14 specifies the shot region to be processed. In the example shown in FIG. 3, the shot region is selected in the order of number from the shot region number=1, and specified as the shot region to be processed. In step S504, the controller 14 calculates the remaining processing time in accordance with the method described with reference to FIG. 4. Here, if information of the processing time required for the calculation is missing, the controller 14 may skip the calculation of the remaining processing time, or may calculate the remaining processing time by using a default value.

In step S505, the controller 14 determines whether the remaining processing time calculated in step S504 matches the conveyance time 54. Here, whether the remaining processing time matches the conveyance time 54 can be determined in consideration of a predetermined margin. For example, if a value obtained by subtracting the conveyance time 54 from the remaining processing time is below a predetermined value, the controller 14 can determine that the remaining processing time matches the conveyance time 54. If it is determined that the remaining processing time matches the conveyance time 54, in step S514, the controller 14 controls the conveyance robot 22 so as to start to convey the next substrate, and advances to step S506.

If it is determined that the remaining processing time does not match the conveyance time 54, the controller 14 advances to step S506 without performing step S514. In step S506, the controller 14 starts to measure the processing time required for the process of the shot region specified in step S503. In step S507, the controller 14 determines whether the shot region specified in step S503 is the leading shot region of the multi dispense group. If YES in step S507, the controller 14 advances to step S508; otherwise, the controller 14 advances to step S515.

In step S508, the controller 14 performs a dispense process in which the imprint material is continuously supplied onto the shot regions forming the multi dispense group to which the shot region (in this case, the leading shot region) specified in step S503 belongs. Then, in step S509, the controller 14 performs an imprint process on the shot region (in this case, the leading shot region) specified in step S503. Then, in step S510, the controller 14 ends the measurement started in step S506, and registers the processing time obtained by the measurement as one sample of the processing time for the processing time group to which the shot region specified in step S503 belongs. This means that the already registered processing time is updated. Here, if two or more processing times are registered for one processing time group, the processing time obtained by statistically processing them (for example, calculating the average value thereof) can be used in step S504. Alternatively, in step S510, the controller 14 may update the already registered processing time based on the newly obtained processing time.

In step S511, the controller 14 determined whether the process of the currently processed substrate ends. If YES in step S511, the controller 14 advances to step S512; otherwise, the controller 14 returns to step S503. In step S512, the controller 14 determines whether the above-described process ends for all the substrates forming the lot. If YES in step S512, the controller 14 advances to step S513; otherwise, the controller 14 advances to step S516. In step S516, the controller 14 controls the conveyance robot 22 so as to exchange the substrate placed on the substrate stage 3 for the next substrate, and then returns to step S503. In step S513, the controller 14 controls the conveyance robot 22 so as to unload the substrate from the substrate stage 3.

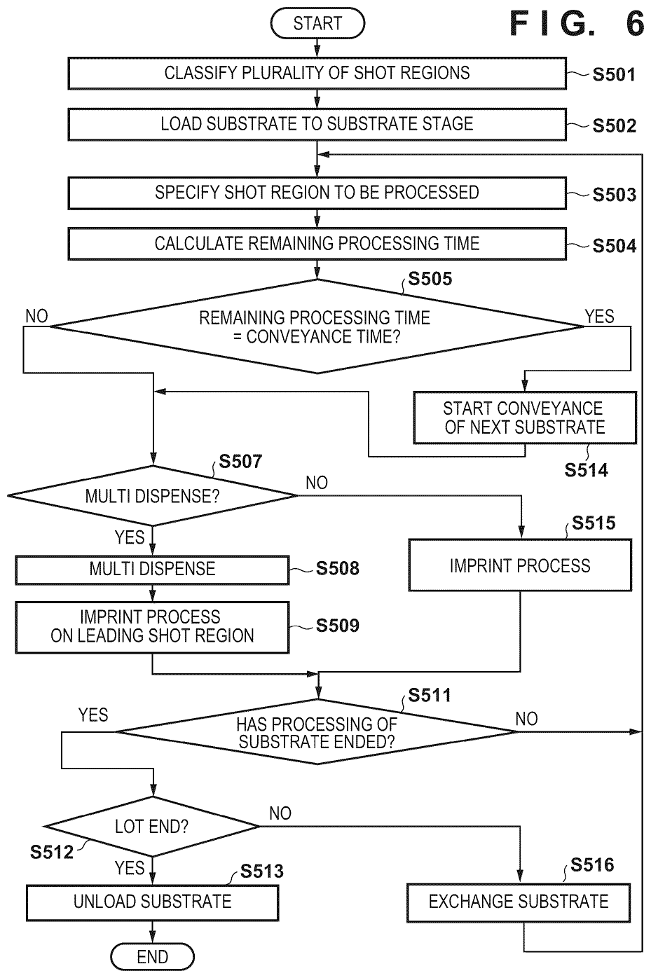

FIG. 6 exemplarily shows an operation of the imprint apparatus 100 in a case in which the processing time has already been associated with each of a plurality of processing time groups. An operation of the imprint apparatus 100 is exemplarily shown. The operation shown in FIG. 6 corresponds to the operation obtained by deleting steps S506 and S510 from the operation shown in FIG. 5. In a case of processing a lot formed from a plurality of substrates, the processing time of each processing time group may be measured using at least one leading substrate, and the operation shown in FIG. 6 may be performed for the subsequent substrates based on the processing time measured as described above.

In the above description, the plurality of shot regions are classified into the plurality of shot regions in accordance with the number of shot regions onto which the imprint material is continuously applied in the dispense process. However, the present invention is not limited to a method of continuously applying the imprint material in the dispense process. The present invention can also be applied to a case in which the plurality of shot regions are classified into the plurality of processing time groups in accordance with a condition other than the number of shot regions onto which the imprint material is continuously applied in the dispense process. Such a condition can be, for example, at least one of the distance between the dispenser and the shot region, the size (or area) of the shot region, the position of the shot region in the substrate, and the like. The distance between the dispenser and the shot region can influence the processing time required for the process of the shot region (for example, the driving time of the substrate). The size of the shot region changes between a full shot region (a shot region having the same shape as the pattern region of the mold) and a partial shot region (a shot region arranged in the periphery of the substrate and having a shape different from the pattern region of the mold). The size (or area) can change among a plurality of partial shot regions. The size of the shot region can influence, for example, the time required to fill a space between the pattern region of the mold and the substrate with the imprint material. The position of the shot region in the substrate can also influence the time required to fill the space between the pattern region of the mold and the substrate with the imprint material.

The pattern of a cured product formed using an imprint apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile or nonvolatile semiconductor memories such as a DRAM, an SRAM, a flash memory, and an MRAM and semiconductor elements such as an LSI, a CCD, an image sensor, and an FPGA. The mold includes an imprint mold or the like.

The pattern of the cured product is directly used as at least some of the constituent members of the above-described articles or used temporarily as a resist mask. After etching or ion implantation is performed in the substrate processing step, the resist mask is removed.

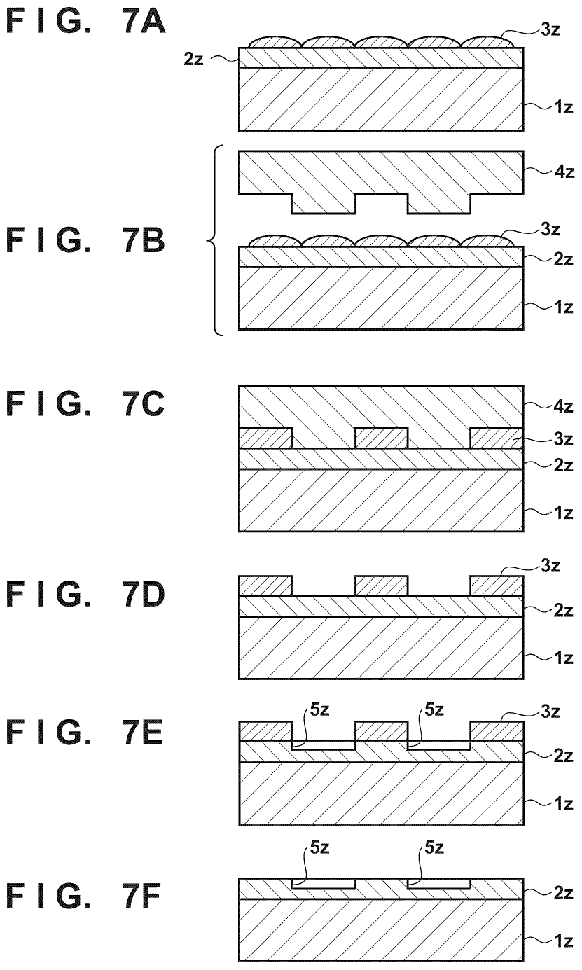

An article manufacturing method in which an imprint apparatus forms a pattern on a substrate, processes the substrate on which the pattern has been formed, and manufactures an article from the processed substrate will be described next. As shown FIG. 7A, a substrate 1z such as a silicon wafer with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

As shown in FIG. 7B, a side of a mold 4z for imprint with a concave-convex pattern is directed toward and made to face the imprint material 3z on the substrate. As shown FIG. 7C, the substrate 1z to which the imprint material 3z has been applied is brought into contact with the mold 4z, and a pressure is applied. The gap between the mold 4z and the processed material 2z is filled with the imprint material 3z. In this state, when the imprint material 3z is irradiated with light as energy for curing via the mold 4z, the imprint material 3z is cured.

As shown in FIG. 7D, after the imprint material 3z is cured, the mold 4z is separated from the substrate 1z, and the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the concave-convex pattern of the mold 4z is transferred to the imprint material 3z.

As shown in FIG. 7E, when etching is performed using the pattern of the cured product as an etching resistant mask, a portion of the surface of the processed material 2z where the cured product does not exist or remains thin is removed to form a groove 5z. As shown in FIG. 7F, when the pattern of the cured product is removed, an article with the grooves 5z formed in the surface of the processed material 2z can be obtained. Here, the pattern of the cured product is removed. However, instead of removing the pattern of the cured product after the process, it may be used as, for example, an interlayer dielectric film included in a semiconductor element or the like, that is, a constituent member of an article.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-205989, filed Dec. 22, 2022, which is hereby incorporated by reference herein in its entirety.

What is claimed is:

1. An imprint apparatus that forms a pattern on each of a plurality of shot regions of a substrate by performing an imprint process, the apparatus comprising
a controller configured to detect a timing at which a time until completion of a process of the substrate matches a predetermined time,
wherein the plurality of shot regions are classified into a plurality of processing time groups, and each processing time group is associated with a processing time required for a process of each shot region belonging to the processing time group, and
wherein the controller is configured to obtain a total time for processing unprocessed shot regions among the plurality of shot regions of the substrate based on the processing time associated with the processing time group to which each of the unprocessed shot regions belongs.

2. The apparatus according to claim 1, further comprising
a dispenser configured to arrange an imprint material on the plurality of shot regions of the substrate,
wherein the dispenser is controlled, based on control information including information used to control an imprint material application process, so as to continuously apply an imprint material onto the designated number of shot regions without undergoing an imprint process, and
wherein the plurality of processing time groups are decided based on the control information.

3. The apparatus according to claim 2, wherein
the controller is configured to classify each of the plurality of shot regions into one of the plurality of processing time groups based on the control information.

4. The apparatus according to claim 3, wherein
the plurality of processing time groups include at least two groups in accordance with the number of shot regions onto which an imprint material is to be continuously applied without undergoing an imprint process.

5. The apparatus according to claim 3, wherein
at least one processing time group of the plurality of processing time groups is formed from a leading shot region on which an imprint material is to be arranged first in a multi dispense group formed from shot regions onto which an imprint material is to be continuously applied without undergoing an imprint process.

6. The apparatus according to claim 5, wherein
at least one other processing time group of the plurality of processing time groups is formed from a subsequent shot region onto which an imprint material is to be applied second or thereafter in the multi dispense group.

7. The apparatus according to claim 5, wherein
a processing time required for a process of the leading shot region includes a time for continuously applying an imprint material onto shot regions forming the multi dispense group to which the leading shot region belongs, and a time required for an imprint process on the leading shot region.

8. The apparatus according to claim 6, wherein
a processing time required for a process of the subsequent shot region includes a time required for an imprint process on the subsequent shot region.

9. The apparatus according to claim 3, wherein
each of at least two processing time groups of the plurality of processing time groups is formed from a leading shot region on which an imprint material is to be arranged first in a multi dispense group formed from shot regions onto which an imprint material is to be continuously applied without undergoing an imprint process.

10. The apparatus according to claim 9, wherein
each of the at least two processing time groups is a processing time group according to the number of shot regions forming the multi dispense group.

11. The apparatus according to claim 10, wherein
a processing time required for a process of a shot region belonging to each of the at least two processing time groups includes a time for continuously applying an imprint material onto shot regions forming a multi dispense group to which the shot region belongs, and a time required for an imprint process on the leading shot region.

12. The apparatus according to claim 1, wherein
based on a time required for a process of a shot region having undergone an imprint process among the plurality of shot regions, the controller updates a processing time associated with a processing time group to which the shot region belongs.

13. The apparatus according to claim 1, further comprising
a substrate stage configured to hold the substrate,
wherein, in accordance with the timing, the controller causes a conveyance robot to start an operation of conveying a substrate to be processed next to the substrate stage.

14. An imprint method of forming a pattern on each of a plurality of shot regions of a substrate, the method comprising:
applying an imprint material onto each of the plurality of shot regions;
forming a pattern by performing an imprint process on the imprint material on each of the plurality of shot regions; and
detecting a timing at which a time until completion of a process of the substrate matches a predetermined time,
wherein
the plurality of shot regions are classified into a plurality of processing time groups, and each processing time group is associated with a processing time required for a process of each shot region belonging to the group, and
the detecting includes obtaining a total time for processing unprocessed shot regions among the plurality of shot regions of the substrate based on the processing time associated with the processing time group to which each of the unprocessed shot regions belongs.

15. The method according to claim 14, further comprising
causing a conveyance robot to start an operation of conveying a substrate to be processed next in accordance with the timing.

16. An article manufacturing method comprising:
forming a pattern on each of a plurality of substrates in accordance with an imprint method defined in claim 14; and
obtaining an article by processing each of the plurality of substrates with the pattern formed thereon.
